(19) United States
(12) Patent Application Publication
(10) Pub. No.: US 2016/0105996 A1
(43) Pub. Date: Apr. 14, 2016

(54) FAN HOLDER FOR A FAN, IN PARTICULAR OF A SWITCH CABINET

(71) Applicant: STEGO-HOLDING GMBH, Schwäbisch Hall (DE)

(72) Inventors: Bernd Armin SCHANZENBACH, Mainhardt (Geisselhardt) (DE); Robert DENT, Schwäbisch Hall (DE); Elmar MANGOLD, Unterschneidheim (Zöbinge) (DE)

(73) Assignee: STEGO-Holding GmbH, Schwäbisch Hall (DE)

(21) Appl. No.: 14/892,677

(22) PCT Filed: May 22, 2014
(86) PCT No.: PCT/EP2014/060550

§ 371 Date: Nov. 20, 2015

(30) Foreign Application Priority Data
May 22, 2013 (DE) 10 2013 105 196.0
Jan. 31, 2014 (DE) 10 2014 101 184.8

(51) Int. Cl. H05K 7/20; F04D 29/70; F04D 29/52; F04D 25/08; F04D 19/00

(52) U.S. Cl. CPC H05K 7/20181; H05K 7/20172; F04D 25/08; F04D 19/002; F04D 29/522; F04D 29/703

(57) ABSTRACT

A fan holder for a fan includes a frame that has an opening through which a gaseous medium flows during operation. The opening forms an accommodating region that is designed to accommodate various replaceable inserts, in particular a filter insert and a flap device, and has at least one retaining device for fastening the particular insert.

### BACKGROUND OF THE INVENTION

1. Field of the Invention

The invention relates to a fan holder for a fan, in particular of a switch cabinet, and to a ventilating device, in particular for a switch cabinet, and to a set comprising a fan holder, at least one flap device and at least one filter mat.

2. Discussion of the Related Art

The prior art discloses fan devices comprising a fan holder and a fan, which is retained by the fan holder. In the case of such fan devices, cold air is taken in via a filter mat comparatively far down in the switch cabinet and is forced out via a (coarse) exit filter mat comparatively high up. This is intended to avoid the introduction of dust and to generate a positive pressure in the cabinet. The fans known in the prior art are considered to be comparatively ineffective and, in particular, not to be particularly variable.

It is therefore an object of the invention to propose a fan holder, a fan device and a set comprising a fan holder, wherein effective cooling can take place, and wherein it is possible to cater in particular in a variable manner for the user's requirements.

### SUMMARY OF THE INVENTION

The object is achieved by a fan holder for a fan, in particular of a switch cabinet, said fan holder having a frame with an opening, through which a gaseous medium flows during operation, wherein the opening forms an accommodating region, which is adapted to accommodate different, interchangeable inserts, in particular a filter insert and a flap device, and has at least one retaining means for fixing the respective insert.

A core idea of the invention is to provide a fan holder in which it is possible to introduce both a flap device and a filter insert. For this purpose, a corresponding retaining device is provided on the frame or in the accommodating region. This means that the user can insert a flap device into the fan holder. Overall, it is possible to cater in a variable manner for the user's particular requirements. It has been found here that the main task of a fan device for switch cabinets is that of cooling the switch cabinet by air circulation. The intention is to avoid the introduction of dust in the process. The latter, however, is not the main task. It has also been found that more effective cooling can be carried out if a filter device is installed in the upper third of a switch cabinet. It has therefore been considered that the air, rather than being expelled from a switch cabinet via a filter mat (which would result in reduced air throughput), should be expelled via a flap device, which results in improved air flow. Prior-art fan devices have always provided a filter mat, in order to achieve corresponding protection against dust. By virtue of an outlet filter being installed in the upper region of the switch cabinet (for example in the upper half, in particular in the upper third, of the switch cabinet), an air stream is distributed uniformly onto the inlet filter, which may be arranged in particular in the lower half, in particular in a lower third, of the switch cabinet. This renders an inlet-filter mat comparatively durable and less polluting. Since the fan holder can accommodate both a flap device and a filter insert, the user of the fan holder can make a choice. The user can therefore choose between improved air circulation or improved dust avoidance.

It is particularly preferred to have a fan holder in which the opening is delimited laterally by retaining surfaces, which retain the respective insert in the frame. In particular, the accommodating region comprises a retaining device, in particular at least one elastic element or at least one latching nose, which subjects the respective insert to a retaining force during operation. This means that a user can readily change over the insert and adapt it to different applications. For example, in order to fix the inserts in the accommodating region, it is possible to arrange an elastic element in each of the corners of the accommodating region, said elastic elements connecting the retaining surfaces.

It is particularly advantageous, moreover, to provide a separable, in particular pivotably mounted, cover, via which the fan holder, in particular the accommodating region thereof, can be closed in the outward direction. The frame of the fan holder forms preferably an, in particular all-round, step, on which the cover can be positioned.

The aforementioned object is also achieved by a set. The set comprises a fan holder according to the invention, a flap device and a filter insert, wherein the flap device and filter insert can be accommodated in the same accommodating region of the fan holder.

The aforementioned object is also achieved by a ventilating device. The ventilating device serves, in particular, for use in or on a switch cabinet and comprises a fan holder according to the invention and also a fan. It is particularly advantageous if the fan is connected to the fan holder via a fan funnel. The fan holder advantageously ensures homogenization of the air stream.

The aforementioned object is also achieved by a flap device. The flap device is provided for use with a fan holder according to the invention and comprises a flap frame, which can be inserted into the accommodating region of the fan holder, and holds at least one, in particular more than one, flap, said flaps, for the purpose of deflecting the flow, at least partially covering over the flap frame. The flaps are advantageously connected in a releasable manner to the flap frame. Furthermore, the fan holder is arranged preferably in the upper half of the switch cabinet, in particular in an upper third of the switch cabinet.

### BRIEF DESCRIPTION OF THE DRAWINGS

The invention is explained in more detail hereinbelow with reference to the drawing, in which:

FIG. 1 shows a schematic exploded illustration of a ventilating device;

FIG. 2 shows a schematic exploded illustration of a fan holder;

FIG. 3 shows a schematic exploded illustration of the fan holder with a flap device according to the invention;

FIG. 4 shows a cross section through an assembled set comprising a fan holder with flap insert, a fan and a cover; and

FIG. 5 shows a schematic illustration of a switch cabinet having two ventilating devices.

### DETAILED DESCRIPTION OF THE INVENTION

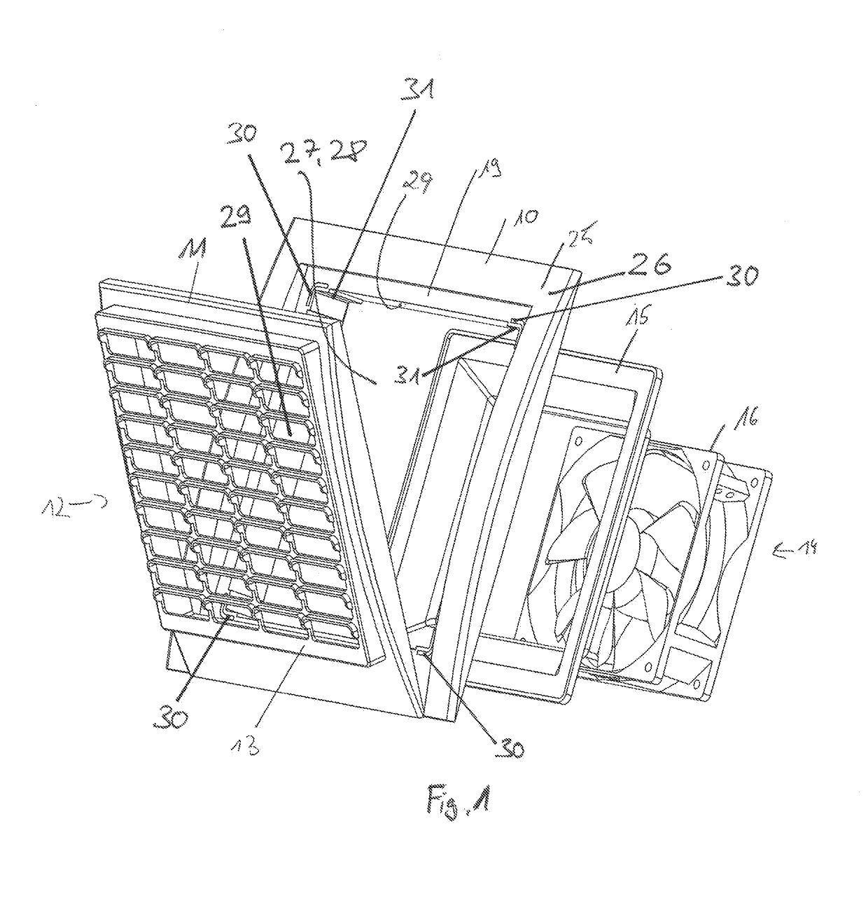

The following description uses the same designations for like, and like acting, parts. FIG. 1 shows a ventilating device comprising a fan holder 10 having a cover 11, which is closed off in the direction of an outer side 12 by a front lattice 13. In the direction of an inner side 14, the fan holder 10 is followed by a fan funnel 15. The fan funnel 15, in turn, is followed by a fan 16. The fan 16 may be designed, in particular, in the form of an axial fan.

In one use example, the ventilating device is connected to a switch cabinet (not shown). The ventilating device here is inserted into an aperture in a switch-cabinet wall and fixed there by a suitable fastening means, which is located in particular on the fan holder 10. The ventilating device thus establishes a connection between the interior of the switch cabinet and the outer region thereof. Depending on the direction of rotation of the fan 16 located in the switch cabinet, air can be taken into the switch cabinet, or expelled therefrom, by the ventilating device.

The fan holder 10 has a frame 26 and an accommodating region 28, which is formed by an opening 27 in the fan holder 10. The fan holder 10 also has an all-round inner step 19, which is formed on the frame 26 and against which the cover 11 can butt in the closed state of the accommodating region 28.

Different inserts can be inserted into the accommodating region 28 of the fan holder 10 and fixed there by suitable retaining means. In particular, the opening 27 is delimited by retaining surfaces 29, which retain the respective insert in the frame. It is further possible to provide specific retaining devices, for example latching, clip-action, rubber or magnetic elements, in order to fix a respective insert in the accommodating region 28. In that embodiment of the invention which is shown in FIG. 1, an insert is retained by elastic elements 30, which subject the insert to a retaining force. The elastic elements 30 are arranged in corners 31 of the accommodating region 28 and, in this way, connect the retaining surfaces 29 to one another.

The accommodating region 28 can be closed by means of the cover 11. In an open state, the cover 11 allows access to the accommodating region 28. The cover 11 is fastened in a removable, preferably pivotable, manner on the fan holder 10, in particular on an edge of the frame 26 which, when the ventilating device is in the installed state, is directed toward the floor. The cover 11 can be arrested in a closed position on the fan holder 10 by suitable snap-fit and/or latching means or the like. The maximum opening angle of the cover 11 in relation to the frame 26 is preferably predetermined by suitable delimiting elements. This makes it possible overall for the inserts to be changed over particularly straightforwardly if required.

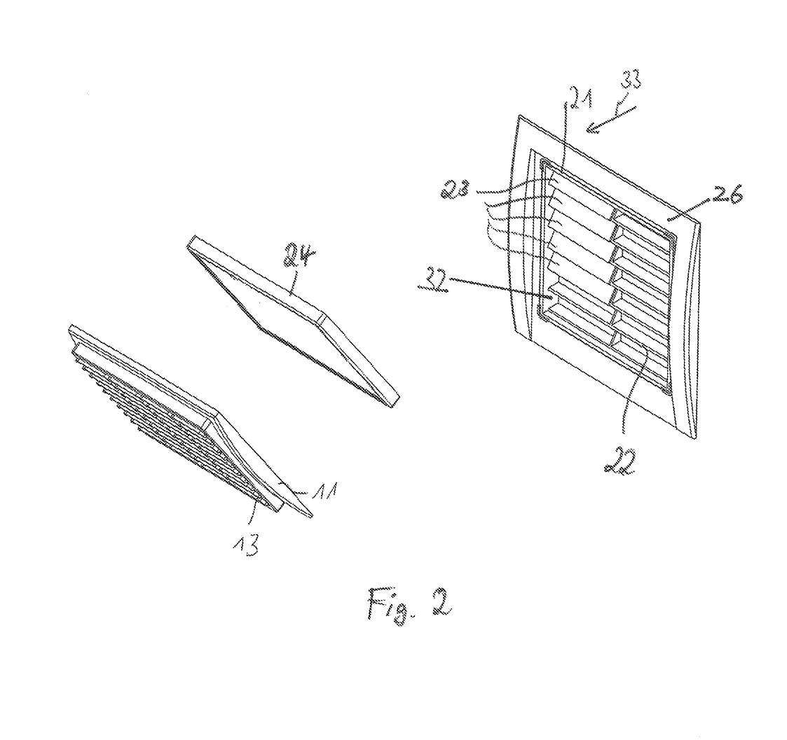

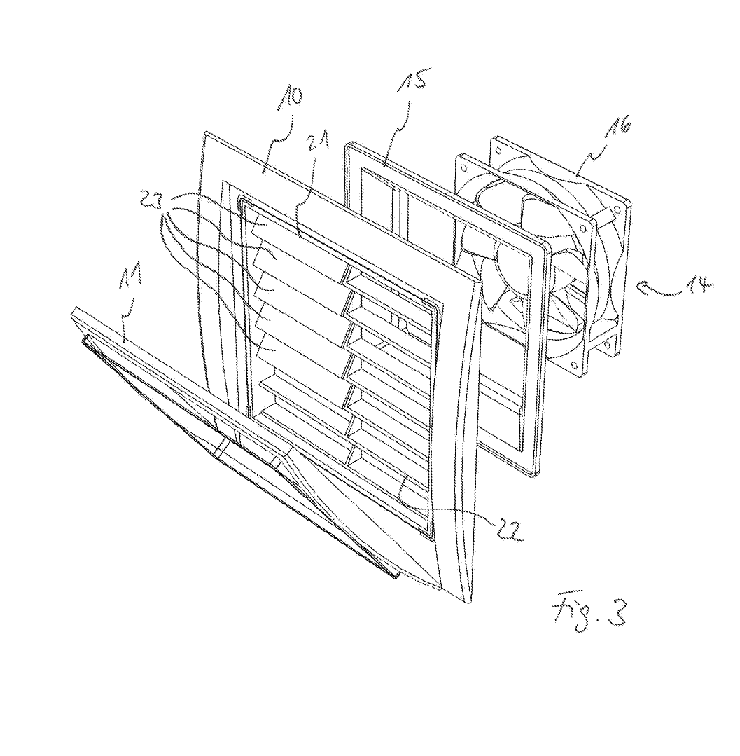

As illustrated in FIGS. 2 and 3, a flap device 21 may be installed, in the form of an interchangeable insert, in the accommodating region 28. The flap device 21 comprises a flap frame 32 and flap-retaining crosspieces 22 as well as a multiplicity of flaps (lamellae) 23 (of which, to give a better view, only five are illustrated). The flaps (lamellae) 23 are mounted, in particular clipped, in a pivotable manner on the retaining crosspieces 22 and can be pivoted by air flowing out from the direction of the arrow 33.

It is conceivable also to provide an active pivoting device (for example an electromotive one). In the installed state, the flap frame 32 has an outer surface butting preferably against the retaining surfaces 29.

As an alternative to the flap device 21, the interchangeable insert used may also be a filter insert 24 (see FIG. 2), which is inserted into the accommodating region 28. The filter insert may be, for example, a filter mat or similar suitable filter element. Whereas, the main purpose of the filter insert is to filter out particles, such as dust or the like, the flap device 21 serves to realize an enhanced air throughput without any filtering of the air flowing through the flap device 21. An end user of the ventilating device, consequently, can decide himself whether to equip the fan holder with a flap device, for optimized air circulation/cooling in a switch cabinet, or with a filter insert, for optimized dust avoidance.

The front lattice 13 may also be in the form of a netting or similar air-permeable material. Furthermore, for cleaning or changeover purposes for example, it may be designed such that it can be released from the cover 11. Without the front lattice 13, the cover 11 forms a rectangular (all-round) frame (having two rectilinearly running edges and two curved edges, the rectilinearly running edges being located opposite one another, as are the curved edges). Similarly, a main body 25 of the fan holder 10 also forms an all-round (rectangular) frame. Two mutually opposite sides of the main body 25 are of rectilinear design; the other mutually opposite sides are curved. In the installed state of the cover 11, the curved sides are in alignment with the curved sides of the main body 25 of the fan holder 10. This achieves a homogeneous unit.

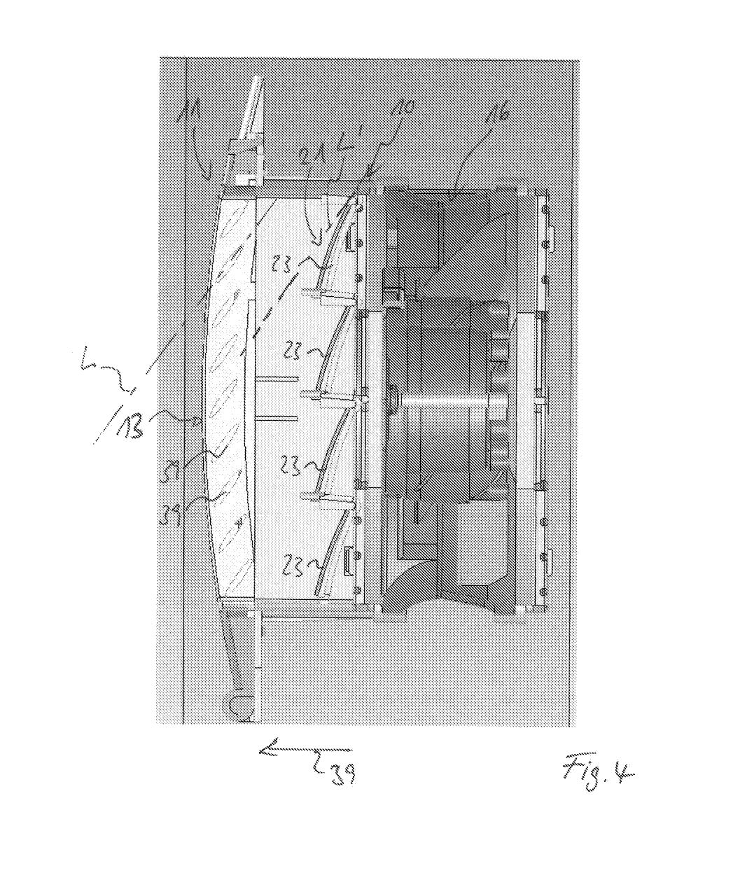

FIG. 4, in addition, shows a cross section through an assembled set comprising a fan holder 10 with a flap insert 21, a fan 16 and a cover 11. It is clear from FIG. 4 that the cover 11, and the front lattice 13 accommodated therein, is arranged in front of the fan holder 10, as seen in the air-exit direction 39. This arrangement with the cover 11 and the front lattice 13 in front of the fan holder advantageously prevents foreign bodies, in particular water, entering into the ventilating device through one or more open flaps 23.

In particular the front lattice 13 in the embodiment shown in FIG. 4 is designed in the form of a diffuser, which prevents liquid, e.g. when it rains, from entering into the interior of the ventilating device and, in particular, into the fan. This is because, when the fan 16 is at a standstill, there is a risk of the flaps 23 opening as a result of a, for example, draft-induced negative pressure or of a mechanical blockage, wherein, consequently, the switch-cabinet interior is open, and dirt, water, etc., could penetrate, when the fan 16 is at a standstill. The diffuser is configured such that it conforms to relative standards, in particular in respect of the safety requirements, and has an ideal flow shape for the exit of air. As FIG. 4 shows, the front lattice 13, for this purpose, has a plurality of through-slots 39, of, in particular, oval or elliptical cross section. The longitudinal axis L of the through-slots 39 is oriented in relation to the flaps 23 such that it is oriented essentially parallel to the flaps 23 in the (fully) open state (see line L′ in FIG. 4). This minimizes the flow resistance of the through-slots 39.

The front lattice 13 can be opened from the outside preferably only with the use of a screwdriver and can be closed from the inside by the catch being locked. This provides for straightforward protection against vandalism. Furthermore, the front lattice 13 is mounted preferably in a rotatable manner in the frame of the cover 11, in order to allow for servicing to be carried out.

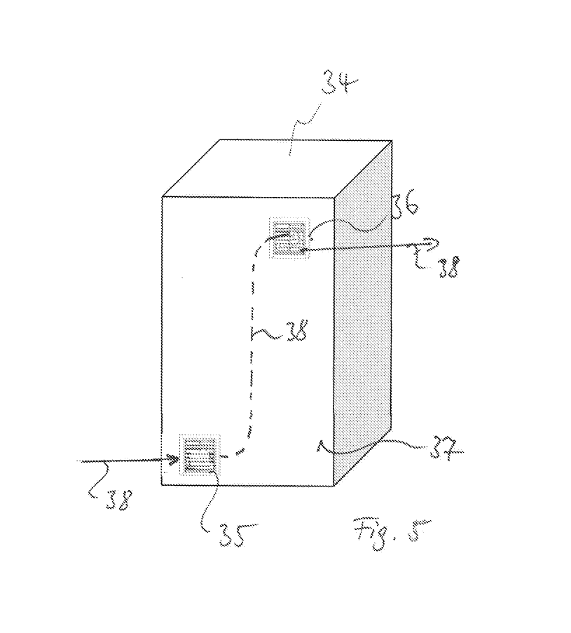

FIG. 5, in addition, shows, schematically, a case where the invention is used with a switch cabinet 34 and two ventilating devices 35 and 36. Whereas the lower ventilating device 35, in the vicinity of the floor, engages through the switch-cabinet wall 37 in a lower third of the latter, the second ventilating device 36 is arranged in an upper third of the switch-cabinet wall 37. Of course, the two ventilating devices need not be arranged in the same switch-cabinet wall.

Provision may advantageously be made for the first, lower ventilating device 35 to form an inlet ventilating device, which has a filter insert, e.g. a filter mat, in the accommodating region 28 and in the case of which a fan takes air into the switch cabinet 34 in order to generate a positive pressure. The positive pressure in the switch cabinet is intended to prevent particles, in particular dust or the like, from entering into the switch cabinet through doors, cable ducts or other openings.

Whereas the prior art, thus far, also equipped the upper ventilating device 36 with a filter insert, in order to reduce further the entrance of particles into the switch cabinet, the ventilating device 36 may advantageously comprise a flap device 21, which is shown in FIGS. 2 and 3, in the accommodating region 28. The upper ventilating device 36 serves as an outlet ventilating device and, consequently, the fan has a direction of rotation which causes air to be expelled from the switch cabinet 34. The air stream which is established in the switch cabinet 34 by way of the lower and upper ventilating devices 35, 36 is indicated in FIG. 5 by the arrow 38. In contrast to a filter mat, the flap device 21 does not reduce the air throughput, and this makes it possible for the switch cabinet 34 to be cooled effectively in the upper region. The result is improved air flow in the switch cabinet, which also has a positive effect on the filter insert in the lower ventilating device 35, since the amount of air taken in is smaller and therefore the air is filtered not just be way of that surface area of the filter insert which corresponds to the impeller of the fan 16, but by way of the entire surface area of the filter. As a result, the air taken in is thus distributed more uniformly overall over the entry filter insert. The filter insert is thus more durable and contamination is reduced. Furthermore, the flap device 21 advantageously prevents undesired foreign bodies, in particular dust, water or the like, from penetrating into the switch cabinet when the fan is at a standstill. This advantageous effect is achieved in that, when the fan is at a standstill, the flaps 23 are closed and thus close off the fan, and the switch-cabinet interior, against foreign bodies. The pivotable mounting of the flaps means that the latter are thus retained in the closed state, preferably by the force of gravity or by an electric motor, when the fan 16 has been switched off. It is only when the fan is in the switched-on state that the flaps 23 are shifted into an open position by the resulting air stream.

The flexible insert options and the modular construction with the aid of the fan holder according to the invention means that both systems can be readily realized by the present invention: on the one hand, it is possible to achieve optimized dust avoidance by it also being possible for the upper fan holder 10 to be readily provided, if required, with a filter insert 24. Furthermore, for optimized air circulation, and thus for optimized cooling at the uppermost location, it is possible, as an alternative, to insert a flap insert 21 into the fan holder, in order to achieve the abovedescribed optimized-cooling function.

The modularity of the system according to the invention provides for a particularly high level of flexibility, allowing a user to adapt the fan holder individually to existing requirements and, if necessary, to change over the inserts in the accommodating region 28 in a particularly straightforward manner.

### LIST OF DESIGNATIONS

10 Fan holder
11 Cover
12 Outer side
13 Front lattice
14 Inner side
15 Fan funnel
16 Fan
19 Step
21 Flap device
22 Retaining crosspieces
23 Flaps
24 Filter insert
25 Main body
26 Frame
27 Opening
28 Accommodating region
29 Retaining surfaces
30 Elastic element
31 Corners
32 Flap frame
33 Arrow
34 Switch cabinet
35 Ventilating device
36 Ventilating device
37 Switch-cabinet wall
38 Arrow
39 Air-exit direction
40 Through-slots
L Longitudinal axis

1. A holder for a fan, the fan holder comprising:
a frame; and
an opening in the frame, the opening for permitting a gaseous medium to flow through the frame during operation of the fan, the opening comprising
an accommodating region to accommodate a filter insert and a flap device, and
a retainer for fixing the filter insert.

2. The fan holder as claimed in claim 1, wherein the opening is delimited laterally by a plurality of retaining surfaces for retaining the filter insert in the frame.

3. The fan holder as claimed in claim 1. wherein the accommodating region comprises a retaining device for applying a retaining force to the respective insert during operation of the fan.

4. The fan holder as claimed in claim 3,
wherein the accommodating region comprises a plurality of corners; and
wherein the retaining device comprises a plurality of elastic elements, one elastic element of the plurality of elastic elements being disposed in a respective corner for connecting the retaining surface.

5. The fan holder as claimed in claim 1, further comprising a cover for closing the accommodating region in an outward direction.

6. The fan holder as claimed in claim 5, wherein the cover has a front lattice, the front lattice comprising a diffuser having a plurality of through-slots.

7. The fan holder as claimed in claim 5, wherein the frame comprises a step for receiving the cover.

8. A set comprising:
a fan holder, a filter insert, and a flap device;
the fan holder comprising
a holding frame;
an opening in the holding frame, the opening for permitting a gaseous medium to flow through the holding frame during operation of the fan, the opening comprising
a single accommodating region, and
a retainer for fixing the filter insert;
wherein the flap device and the filter insert are accommodated in the single accommodating region.

9. A device for a switch cabinet the ventilating device comprising:
a fan, a fan holder, a filter insert, and a flap device;
the fan holder comprising
a frame; and
an opening in the frame, the opening for permitting a gaseous medium to flow through the frame during operation of the fan, the opening comprising
an accommodating region to accommodate the filter insert and the flap device, and
a retainer for fixing the filter insert.

10. The ventilating device as claimed in claim 9,
further comprising a fan funnel;
wherein the fan is connected to the fan holder via the fan funnel.

11. The set as claimed in claim 8, wherein the flap device comprises a flap frame and a plurality of flaps the flap frame being inserted into the single accommodating region.

12. The set as aimed in claim 11, wherein when the fan is not operating the flaps are closed.

13. The set as claimed in claim 11, wherein the plurality of flaps are releasably connected to the flap frame.

14. A ventilating device as claimed in claim 9,
further comprising a cover for closing the accommodating region in an outward direction;
wherein the cover has a front lattice, the front lattice comprising a diffuser having a plurality of through-slots;
wherein the flap device comprises a plurality of flaps; and
wherein a longitudinal axis of the through-slots is oriented substantially parallel to the plurality of flaps when the flaps are open.

15. A ventilating device in combination with a switch cabinet, the ventilating device comprising:
a fan, a fan holder, a filter insert, and a flap device;
the fan holder comprising
a frame;
an opening in the frame, the opening for permitting a gaseous medium to flow through the frame during operation of the fan, the opening comprising
an accommodating region to accommodate the filter insert and the device, and
a retainer for fixing the filter insert;
wherein the fan holder is arranged in an upper third of the switch cabinet.

16. The fan holder as claimed in claim 3, wherein the retaining device is an elastic element or a latching nose.

17. The fan holder as claimed in claim 6, wherein at least on through-slot has an elliptical cross section.
